(19) United States
(12) Patent Application Publication
(10) Pub. No.: US 2011/0102997 A1
(43) Pub. Date: May 5, 2011

(54) MASS STORAGE DEVICE AND METHOD OF ACCESSING MEMORY DEVICES THEREOF

(75) Inventor: Franz Michael Schuette, Colorado Springs, CO (US)

(73) Assignee: OCZ TECHNOLOGY GROUP, INC., San Jose, CA (US)

(21) Appl. No.: 12/917,641

(22) Filed: Nov. 2, 2010

Related U.S. Application Data
(60) Provisional application No. 61/257,110, filed on Nov. 2, 2009.

(51) Int. Cl. G06F 1/16; H05K 7/00

(52) U.S. Cl. 361/679.32

(57) ABSTRACT

A mass storage device configured to enable accessing of an array of solid-state memory devices on the storage device in the event of a memory controller failure on the storage device. The storage device includes a printed circuit board, an array of non-volatile solid-state memory devices on the printed circuit board, a system interface connector on the printed circuit board and adapted to connect the mass storage device to a host system, and an onboard memory controller on the printed circuit board and adapted to communicate between the host system and the memory devices. The mass storage device further includes an auxiliary connector on the printed circuit board that is separate from and in addition to the system interface connector. The auxiliary connector provides a direct path for accessing the memory devices that is separate from the onboard memory controller.

### CROSS REFERENCE TO RELATED APPLICATIONS

This application claims the benefit of U.S. Provisional Application No. 61/257,110, filed Nov. 2, 2009, the contents of which are incorporated herein by reference.

### BACKGROUND OF THE INVENTION

The present invention generally relates to mass storage devices for use with computers and other processing apparatuses. More particularly, this invention relates to a mass storage device having non-volatile (permanent memory-based) memory devices that can be accessed in the event of a memory controller failure.

Mass storage devices such as advanced technology (ATA) or small computer system interface (SCSI) drives are rapidly adopting non-volatile memory technology, such as flash memory devices (chips) or another emerging solid-state memory technology, including phase change memory (PCM), resistive random access memory (RRAM), magnetoresistive random access memory (MRAM), ferromagnetic random access memory (FRAM), organic memories, or nanotechnology-based storage media such as carbon nanofiber/nanotube-based substrates. Currently the most common solid-state technology uses NAND flash memory devices as inexpensive storage memory.

Device failure leading to loss of data has been a common problem with standard hard disk drives (HDDs) and can generally be attributed to three separate root causes, namely, interface failure, controller failure, and media failure. In the case of interface failure, physical damage often has occurred to the connector, specifically, contacts are either bent or broken, thus preventing connection of the drive to the host computer. In the case of controller failure, the integrated circuit (IC) of the controller has typically been damaged or the integrated firmware corrupted. Media failure in this context is meant to include damage to the platter as well as to the motor and/or actuator.

Data recovery from mass storage devices that have failed as a result of any of these three scenarios is generally performed by specialized businesses and can be very costly. In the case of the first two scenarios, an effective workaround can often be achieved by taking a second drive of the same model and connecting it to the media portion of the damaged drive to access the data and copy them to a safe location. In the case of solid-state drives, that is, mass storage devices equipped with non-volatile memory devices, this is no longer possible since the memory devices are typically integrated on the circuit board on which the controller is mounted, and as a result the memory devices cannot be connected to a different controller without reworking the entire board. At this point, high temperatures required for reflowing solder connections of the circuit board can effectively destroy the data on non-volatile memory devices, for example, flash memory and phase change memory chips. It would therefore be desirable to be able to access the data on a solid-state drive whose controller has failed.

### BRIEF DESCRIPTION OF THE INVENTION

The present invention provides a mass storage device configured to enable accessing of an array of solid-state memory devices on the storage device in the event of a memory controller failure on the storage device.

According to a first aspect of the invention, the mass storage device includes a printed circuit board, an array of non-volatile solid-state memory devices on the printed circuit board, a system interface connector on the printed circuit board and adapted to connect the mass storage device to a host system, and an onboard memory controller on the printed circuit board and adapted to communicate between the host system and the memory devices. The mass storage device further includes an auxiliary connector on the printed circuit board that is separate from and in addition to the system interface connector. The auxiliary connector provides a direct path for accessing the memory devices that is separate from the onboard memory controller. The auxiliary connector is preferably adapted to enable access of the memory devices, for example, to recover data on the memory devices, by connecting to the auxiliary connector an external module equipped with a memory controller that is separate from and in addition to onboard memory controller.

According to a second aspect of the invention, a method is provided for accessing data from an array of non-volatile memory devices on a printed circuit board of a mass storage drive that further has a system interface connector adapted to connect the mass storage device to a host system and an onboard memory controller adapted to communicate between the host system and the memory devices. The method includes providing an auxiliary connector on the mass storage device that is separate from and in addition to the system interface connector and provides a direct path for accessing the memory devices that is separate from the onboard memory controller, and then accessing the memory devices through the auxiliary connector without involving the onboard memory controller.

A significant advantage of this invention is the ability to bypass an existing onboard memory controller of a mass storage device to directly access solid-state memory devices of the storage device. As a result, access to data on the memory devices can be performed even in the event of failure of the onboard memory controller, enabling the data to be recovered and written to a host system.

Other aspects and advantages of the invention will be better appreciated from the following detailed description.

### BRIEF DESCRIPTION OF THE DRAWINGS

FIG. 1 schematically represents a conventional solid-state drive, wherein data access from an array of solid-state memory devices is only possible via a memory controller on the drive.

FIG. 2 schematically represents a solid-state drive that includes an auxiliary connector that enables direct access to solid-state memory devices of the drive without use of a memory controller on the drive in accordance with an embodiment of the invention.

FIG. 3 schematically represents an external module plugged into the auxiliary connector of FIG. 2 and connected to a host computer for data transfer in accordance with an embodiment of the invention.

### DETAILED DESCRIPTION OF THE INVENTION

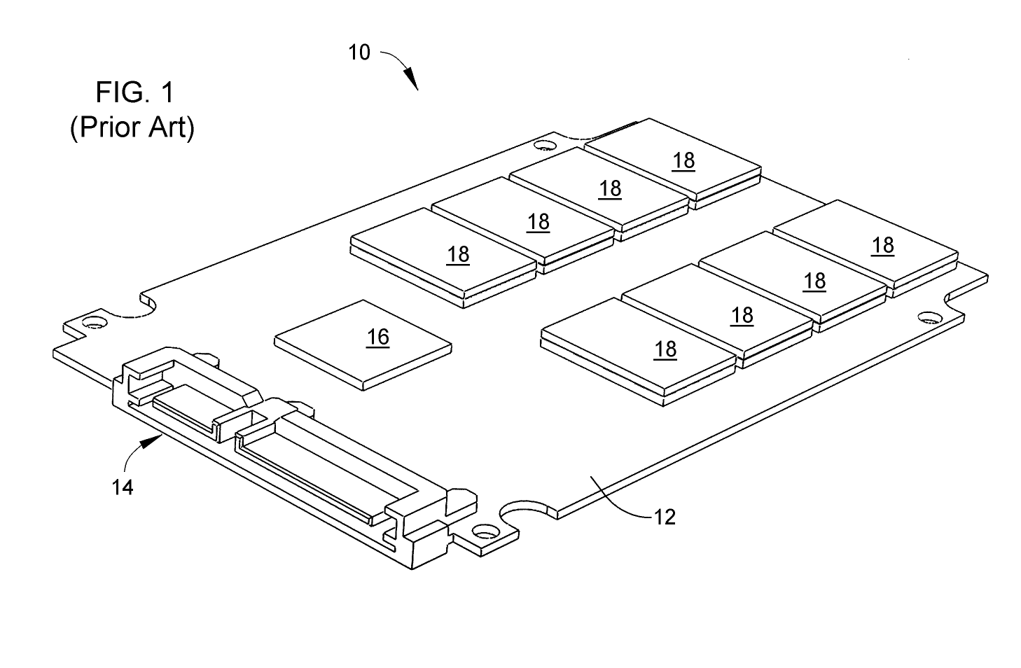

FIG. 1 schematically represents a non-volatile memory-based mass storage device, represented as a solid-state drive (SSD) 10 of a type known in the art. The SSD 10 is shown as including a printed circuit board (PCB) 12 having a system interface connector 14. As understood in the art, the interface connector 14 is adapted to enable the SSD 10 to be accessed by a host system (not shown), which may be a personal computer or any other suitable type of processing apparatus equipped with a data and control bus for interfacing with the SSD 10. The bus may operate with any suitable protocol known in the art, preferred but nonlimiting examples being the advanced technology attachment (ATA) bus, particularly SATA, as well as the small computer system interface (SCSI) and particularly the serially-attached SCSI (SAS). The SSD 10 further includes a memory controller 16 mounted on the PCB 12, for example, a SATA-flash controller, and an array of non-volatile memory devices 18, for example, NAND flash memory devices (IC chips) or any other form of non-volatile memory. The SSD 10 may further include cache (not shown), for example, fast cache of DRAM or SRAM. Suitable components for the controller 16 and cache are well known in the art and therefore will not be described in any detail here.

Protocol signals received from the host system through the system interface connector 14 are translated by an abstraction layer of the controller 16 from logical to physical addresses of the memory devices 18, to which data are written or from which data are read. Control and data lines (not shown) are formed as metal lines or traces on the PCB 12 and connect the controller 16 to the array of memory devices 18. In the event of failure of the controller 16, communication between the interface connector 14 and memory devices 18 is lost. The memory devices 18 cannot be connected to a different controller without replacing the controller 16 or reworking the control and data lines on the PCB 12. Unfortunately, doing so involves reflowing solder connections on the PCB 12 that can effectively destroy the data on the memory devices 18, particularly if the devices 18 are flash memory or phase change memory chips.

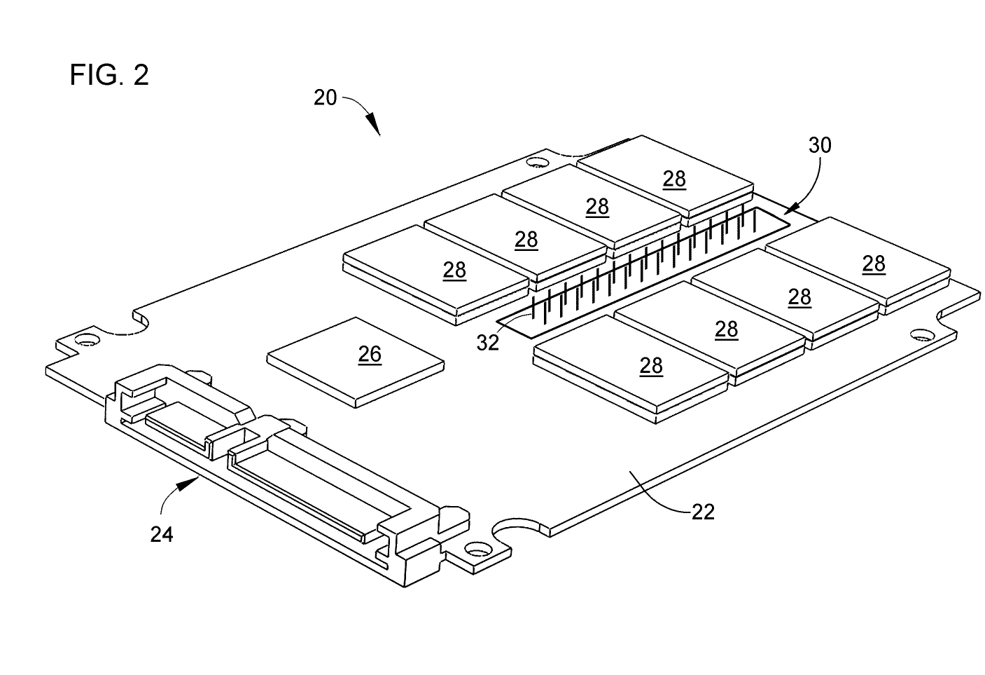

FIG. 2 represents an SSD 20 of a type similar to that shown in FIG. 1, and as such is represented as comprising a PCB 22, a system interface connector 24, an onboard memory controller 26, and non-volatile memory devices 28, as a nonlimiting example, NAND flash memory devices. As with the SSD 10 of FIG. 1, a typical application of the SSD 20 would be to install the SSD 20 in a host system (not shown), for example, a personal computer or any other suitable type of processing apparatus, which is then used to access the SSD 20 to read and write data to and from its memory devices 28. However, the SSD 20 further includes an auxiliary connector (port or header) 30 attached to the PCB 12. The connector 30 is represented as comprising male pins 32 for providing electrical connections to a suitably-configured female connector (not shown). The pins 32 are connected with control and data lines (not shown) of the SSD 20 so that the connector 30 is adapted to directly interface with the memory devices 28. As such, the connector 30 provides a direct path for accessing the memory devices 28 that is separate from the onboard memory controller 26.

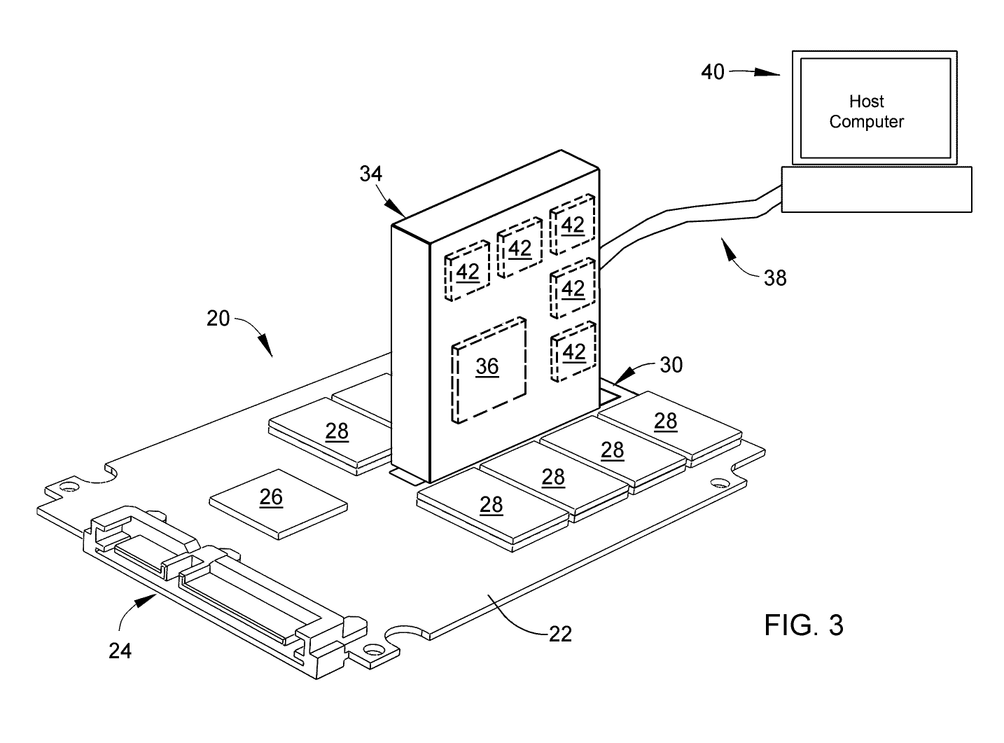

The auxiliary connector 30 enables an external module 34 (FIG. 3) that is separate from the SSD 20 and equipped with an appropriate connector (not shown) to be directly connected to the PCB 22. According to a preferred aspect of the invention, the connector 30 and module 34 enable the module 34 to be freely connected and disconnected from the SSD 20, without requiring soldering or any other action that could result in damage to the memory devices 28. The module 34 is represented as including a memory controller 36, such that protocol signals can be received through a standard data connector 38 from a host system 40, such as a computer or workstation, and translated by an abstraction layer of the controller 36 from logical to physical addresses of the memory devices 28 on the PCB 22. The host system 40 can be a conventional computer or workstation, or may be a computer or workstation specially adapted to operate with the module 34. Furthermore, the host system 40 may be in addition to and separate from the original host system in which the SSD 20 was originally installed or otherwise operating with. However, it is also within the scope of the invention that the host system 40 could be the original host system, in which case the auxiliary connector 30 and data connector 38 provide a different communication route between the host system 40 and the SSD 20 than was originally provided through the system interface 24.

According to one preferred aspect of the invention, the module 34 can be adapted as a data recovery module to enable writing and reading of data to and from the memory devices 28. As a result, in the event of failure of the controller 26 on the PCB 22, resulting in the loss of communication between the system interface connector 24 and the memory devices 28, the module 34 enables the memory devices 28 to be connected to the controller 36 of the module 34 without replacing the controller 26 of the SSD 20 and without reworking the control and data lines on the PCB 22. Data retrieved from the memory devices 18 can be transferred to the host system 40 through the standard data connector 38.

In addition to the above, the module 34 can be adapted to enable a user to disable the onboard memory controller 26 in the event the controller 26 interferes with the data recovery process. Another option is that the controller 36 may be adapted to only access raw data from the memory devices 28, which are then reconstructed to the original content of the SSD 20 on the host system 40.

According to another preferred aspect of the invention, the module 34 can be adapted as a diagnostic module. This functionality can be in addition to or in place of the capacity of the module 34 to perform data recovery. Since the command and data traces from the module's controller 36 to the memory devices 28 use the same contacts on the memory devices 28 that are used for standard operation, they are also electrically connected to the onboard memory controller 26. In this manner, the auxiliary connector 30 can be used as a test port for the controller 26, in which case the module 34 may require the controller 36 to have a diagnostic functionality, which could, for example, include a dummy array of memory devices 42. Alternatively, the module 34 may include the controller 36 to access data on the array of memory devices 28 without involving the onboard memory controller 26.

The memory controller 36 of the module 34 preferably has the exact same configuration as the onboard memory controller 26 on the SSD 20, that is, the very same controller IC is used along with the very same firmware, which contains data regarding the physical configuration of the array of memory devices 28 as well as internal configuration data that can be vital for correct addressing of data in coherent blocks of memory. Because only a few variations of memory controllers are typically in circulation at any given time, the invention can be implemented by offering different external modules 34 having controllers 36 with different configurations (different ICs and firmware) corresponding to the different controller configurations existing in the market. As a result, a user would typically need to have only a small number of different modules 34 on hand in order to service the majority of SSDs in the field.

Differences in firmware versions on the controllers 26 and 36 can occur as new features are added to existing firmware in order to perform housekeeping tasks, for example, garbage collection or TRIM algorithms, either of which may alter the physical data structure on the array of memory devices 28. If the existing firmware of the controller 26 is not known, the module 34 can be used to access the original controller 26 to receive information of the firmware version used by the SSD 20. The firmware on the module 34 can be easily reprogrammed with the host system 40 using conventional software and the standard data connector 38 or a diagnostic header (not shown). In most instances, it will be preferable to supply power to the SSD 20 using the original power connector of the system interface connector 24. However, it is also possible to integrate power supply connections within the module 34 to supply power to the SSD 20 through the auxiliary connector 30.

While the invention has been described in terms of specific embodiments, it is apparent that other forms could be adopted by one skilled in the art. For example, the physical configuration of the non-volatile memory mass storage device (SSD 20) could differ from that shown. Therefore, the scope of the invention is to be limited only by the following claims.

1. A mass storage device comprising:
a printed circuit board;
an array of non-volatile solid-state memory devices on the printed circuit board;
a system interface connector on the printed circuit board and adapted to connect the mass storage device to a host system;
an onboard memory controller on the printed circuit board and adapted to communicate between the host system and the memory devices; and
an auxiliary connector on the printed circuit board that is separate from and in addition to the system interface connector, the auxiliary connector providing a direct path for accessing the memory devices that is separate from the onboard memory controller.

2. The mass storage device of claim 1, further comprising an external module configured to be directly connected to the auxiliary connector and operable to access data on the memory devices without involving the onboard memory controller.

3. The mass storage device of claim 2, wherein the external module has a memory controller that is separate from and in addition to the onboard memory controller of the mass storage device.

4. The mass storage device of claim 3, wherein the external module is operable to recover data on the memory devices and transmit the data to the host system or a second host system when the external module is connected to the auxiliary connector.

5. The mass storage device of claim 3, wherein the external module is operable to disable the onboard memory controller when the external module is connected to the auxiliary connector.

6. The mass storage device of claim 3, wherein the external module is operable to perform diagnostics on the onboard memory controller when the external module is connected to the auxiliary connector.

7. The mass storage device of claim 3, wherein the external module is adapted to supply power to the mass storage device when the external module is connected to the auxiliary connector.

8. The mass storage device of claim 3, wherein the external module is adapted to access firmware on the onboard memory controller when the external module is connected to the auxiliary connector.

9. The mass storage device of claim 1, wherein the memory devices are NAND flash memory devices.

10. The mass storage device of claim 1, wherein the host system is a personal computer or a workstation.

11. A method for accessing data from an array of non-volatile memory devices on a printed circuit board of a mass storage device that further has a system interface connector adapted to connect the mass storage device to a host system and an onboard memory controller adapted to communicate between the host system and the memory devices, the method comprising:
providing an auxiliary connector on the mass storage device that is separate from and in addition to the system interface connector and provides a direct path for accessing the memory devices that is separate from the onboard memory controller; and
accessing the memory devices through the auxiliary connector without involving the onboard memory controller.

12. The method of claim 11, wherein the accessing step comprises reading data from the memory devices and transferring the data to the host system or a second host system.

13. The method of claim 11, further comprising the step of connecting an external module to the auxiliary connector, wherein the accessing step is performed with the external module through the auxiliary connector.

14. The method of claim 13, wherein the external module accesses the memory devices with a memory controller that is separate from and in addition to the onboard memory controller of the mass storage device.

15. The method of claim 14, wherein the accessing step comprises disabling the onboard memory controller with the external module.

16. The method of claim 13, wherein the accessing step comprises performing diagnostics on the onboard memory controller with the external module.

17. The method of claim 13, wherein the accessing step comprises supplying power to the mass storage device with the external module.

18. The method of claim 13, wherein the accessing step comprises accessing firmware on the onboard memory controller with the external module.

19. The method of claim 11, wherein the memory devices are NAND flash memory devices.

20. The method of claim 11, wherein the host system is a personal computer or a workstation.
